(19) United States
(12) Patent Application Publication
(10) Pub. No.: US 2026/0267235 A1
(43) Pub. Date: Sep. 10, 2026

(54) ALIGNMENT METHOD AND ASSOCIATED ALIGNMENT AND LITHOGRAPHIC APPARATUSES

(71) Applicant: ASML Netherlands B.V., Veldhoven (NL)

(72) Inventors: Nick Franciscus Wilhelmus THISSEN, Eindhoven (NL); Simon Gijsbert Josephus MATHIJSSEN, Rosmalen (NL)

(73) Assignee: ASML Netherlands B.V., Veldhoven (NL)

(21) Appl. No.: 18/873,263

(22) PCT Filed: Oct. 23, 2023
(86) PCT No.: PCT/EP2023/079397

§ 371 Date: Dec. 9, 2024

(30) Foreign Application Priority Data
Nov. 9, 2022 (EP) 22206356.2

(51) Int. Cl. G03F 7/00

(52) U.S. Cl. CPC G03F 7/70633; G03F 7/70608; G03F 7/706831; G03F 7/706837; G03F 7/706839; G03F 7/706845

(57) ABSTRACT

Disclosed is a method for determining at least one set of correction weights to correct metrology data is disclosed. The method comprises obtaining first and second metrology data relating respectively to a first layer and a second layer. Each of the first and second metrology data is fitted to a model for representing the metrology data to determine a first set of fit residuals and second set of fit residuals. The at least one set of correction weights as at least one set of correction weights are determined to minimize a difference between said first set of fit residuals and said second set of fit residuals.

### CROSS-REFERENCE TO RELATED APPLICATIONS

This application claims priority of EP application 22206356.2 which was filed on Nov. 9, 2022 and which is incorporated herein in its entirety by reference.

### BACKGROUND

### Field of the Invention

The present invention relates to methods and apparatus usable, for example, in the manufacture of devices by lithographic techniques, and to methods of manufacturing devices using lithographic techniques. The invention relates to metrology devices, and more specifically metrology devices used for measuring position such as alignment sensors and lithography apparatuses having such an alignment sensor.

### Background Art

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. These target portions are commonly referred to as “fields”.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down (by the same apparatus or a different lithographic apparatus) in previous layers. For this purpose, the substrate is provided with one or more sets of alignment marks. Each mark is a structure whose position can be measured at a later time using a position sensor or alignment sensor (both terms are used synonymously), typically an optical position sensor.

The lithographic apparatus includes one or more alignment sensors by which positions of marks on a substrate can be measured accurately. Different types of marks and different types of alignment sensors are known from different manufacturers and different products of the same manufacturer. A type of sensor widely used in current lithographic apparatus is based on a self-referencing interferometer as described in U.S. Pat. No. 6,961,116 (den Boef et al). Various enhancements and modifications of the position sensor have been developed, for example as disclosed in US2015261097A1. The contents of all of these publications are incorporated herein by reference.

Imperfections in alignment marks can result in a wavelength/polarization dependent variation in a measured value from that mark. As such, correction and/or mitigation for this variation is sometimes effected by performing the same measurement using multiple different wavelengths and/or polarizations (or more generally, multiple different illumination conditions).

One method to minimize errors resultant from such mark imperfections is to use a weighted average between two or more colors, where the color weights are found by minimizing the residuals of the wafer model fit. Such an approach may be referred to as a multi-color lowest residuals (MCLR) method, and is described in WO2022184405A1, which is incorporated herein by reference. The measurements of each color can be individually modeled to obtain model residuals per color, and then a fit (e.g., a least square fit) can be performed to find the optimal color weights that minimize the model residuals over the wafer or set of wafers.

It would be desirable to improve one or more aspects of measuring using multiple illumination conditions, such as describe in WO2022184405A1, at least in certain applications or use cases.

### SUMMARY OF THE INVENTION

The invention in a first aspect provides a method for determining at least one set of correction weights to correct metrology data comprising: obtaining first metrology data relating to a first set of illumination settings of measurement radiation used to perform a measurement of a first layer; fitting the first metrology data to a model for representing the metrology data and determining a first set of fit residuals as the residuals of said first metrology data with respect to the model; obtaining second metrology data relating to a second set of illumination settings of measurement radiation used to perform a measurement of a second layer, said second set of illumination settings comprising a plurality of illumination settings, where each illumination setting comprises a different wavelength, polarization or combination thereof; fitting the second metrology data to a model for representing the metrology data and determining a second set of fit residuals as the residuals of said second metrology data with respect to the model; and determining said at least one set of correction weights as at least one set of correction weights which minimize a difference between said first set of fit residuals and said second set of fit residuals.

Also disclosed is a computer program, alignment sensor and a lithographic apparatus being operable to perform the method of the first aspect.

The above and other aspects of the invention will be understood from a consideration of the examples described below.

### BRIEF DESCRIPTION OF THE DRAWINGS

Embodiments of the invention will now be described, by way of example only, with reference to the accompanying drawings, in which:

FIG. 1 depicts a lithographic apparatus;

FIG. 2 illustrates schematically measurement and exposure processes in the apparatus of FIG. 1;

FIG. 3 is a schematic illustration of an alignment sensor adaptable according to an embodiment of the invention;

FIG. 4 is a flowchart of a color selection method in accordance with an embodiment of the invention;

FIG. 5 conceptually illustrates an example of indirect alignment, showing how two layers may each be reference to a reference layer, or to each other; and

FIG. 6 conceptually illustrates an example of indirect alignment, with overlay between a top layer pair and an immediately preceding layer pair shown.

### DETAILED DESCRIPTION OF EMBODIMENTS

Before describing embodiments of the invention in detail, it is instructive to present an example environment in which embodiments of the present invention may be implemented.

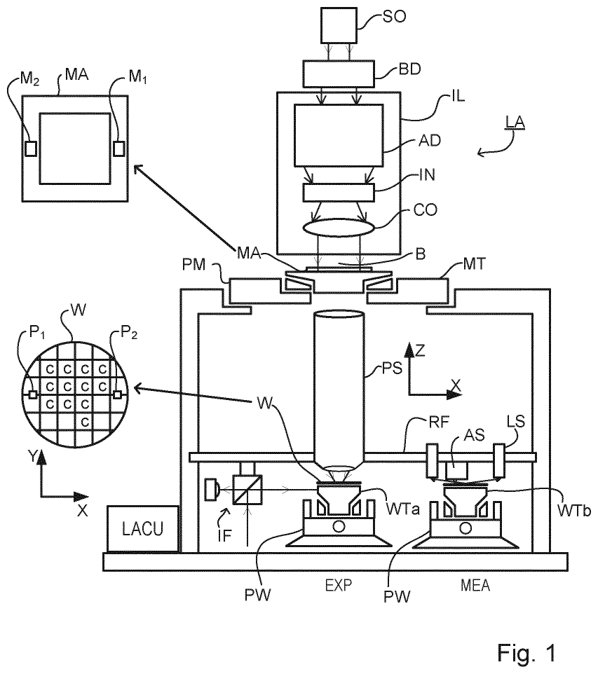

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA—between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

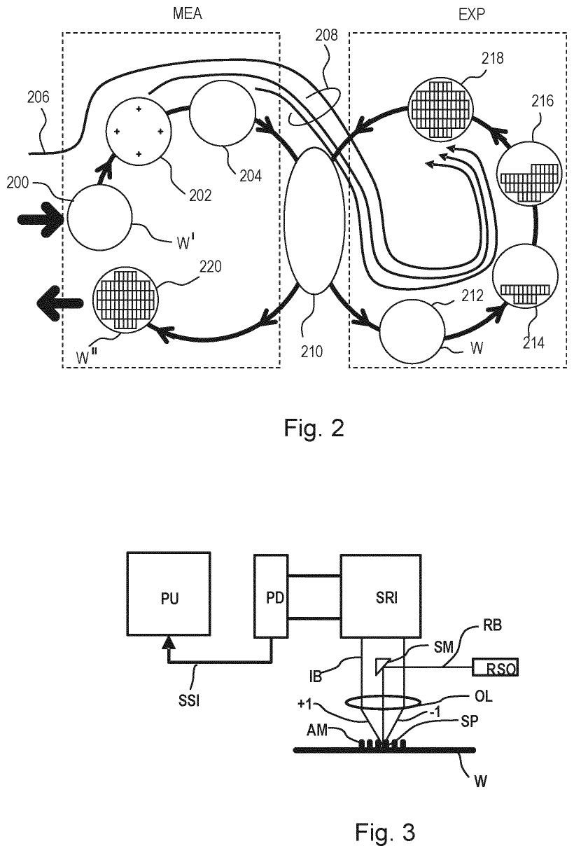

FIG. 2 illustrates the steps to expose target portions (e.g. dies) on a substrate W in the dual stage apparatus of FIG. 1. On the left hand side within a dotted box are steps performed at a measurement station MEA, while the right hand side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. These processing steps progressively introduce distortions in the substrate that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid”, which maps very accurately the distribution of marks across the substrate, including any distortion relative to a nominal rectangular grid.

At step 204, a map of wafer height (Z) against X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. To these recipe data are added the measurements of wafer position, wafer grid and height map that were made at 202, 204, so that a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the ‘ideal’ grid, in different dimensions. Advanced models are known that use more parameters.

At 210, wafers W′ and Ware swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example rather than measuring alignment in a single pass, often there will be separate phases of coarse and fine measurement, using the same or different marks. The coarse and/or fine alignment measurement steps can be performed before or after the height measurement, or interleaved.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down in previous layers (by the same apparatus or a different lithographic apparatus). For this purpose, the substrate is provided with one or more sets of marks. Each mark is a structure whose position can be measured at a later time using a position sensor, typically an optical position sensor. The position sensor may be referred to as “alignment sensor” and marks may be referred to as “alignment marks”.

A lithographic apparatus may include one or more (e.g. a plurality of) alignment sensors by which positions of alignment marks provided on a substrate can be measured accurately. Alignment (or position) sensors may use optical phenomena such as diffraction and interference to obtain position information from alignment marks formed on the substrate. An example of an alignment sensor used in current lithographic apparatus is based on a self-referencing interferometer as described in U.S. Pat. No. 6,961,116. Various enhancements and modifications of the position sensor have been developed, for example as disclosed in US2015261097A1. The contents of all of these publications are incorporated herein by reference.

A mark, or alignment mark, may comprise a series of bars formed on or in a layer provided on the substrate or formed (directly) in the substrate. The bars may be regularly spaced and act as grating lines so that the mark can be regarded as a diffraction grating with a well-known spatial period (pitch). Depending on the orientation of these grating lines, a mark may be designed to allow measurement of a position along the X axis, or along the Y axis (which is oriented substantially perpendicular to the X axis). A mark comprising bars that are arranged at +45 degrees and/or −45 degrees with respect to both the X- and Y-axes allows for a combined X- and Y-measurement using techniques as described in US2009/195768A, which is incorporated by reference.

The alignment sensor scans each mark optically with a spot of radiation to obtain a periodically varying signal, such as a sine wave. The phase of this signal is analyzed, to determine the position of the mark and, hence, of the substrate relative to the alignment sensor, which, in turn, is fixated relative to a reference frame of a lithographic apparatus. So-called coarse and fine marks may be provided, related to different (coarse and fine) mark dimensions, so that the alignment sensor can distinguish between different cycles of the periodic signal, as well as the exact position (phase) within a cycle. Marks of different pitches may also be used for this purpose.

Measuring the position of the marks may also provide information on a deformation of the substrate on which the marks are provided, for example in the form of a wafer grid. Deformation of the substrate may occur by, for example, electrostatic clamping of the substrate to the substrate table and/or heating of the substrate when the substrate is exposed to radiation.

FIG. 3 is a schematic block diagram of an embodiment of a known alignment sensor AS. Radiation source RSO provides a beam RB of radiation of one or more wavelengths, which is diverted by diverting optics onto a mark, such as mark AM located on substrate W, as an illumination spot SP. In this example the diverting optics comprises a spot mirror SM and an objective lens OL. The illumination spot SP, by which the mark AM is illuminated, may be slightly smaller in diameter than the width of the mark itself.

Radiation diffracted by the mark AM is collimated (in this example via the objective lens OL) into an information-carrying beam IB. The term “diffracted” is intended to include complementary higher diffracted orders; e.g.,: +1 and −1 diffracted orders (labelled+1, −1) and optionally zero-order diffraction from the mark (which may be referred to as reflection). A self-referencing interferometer SRI, e.g. of the type disclosed in U.S. Pat. No. 6,961,116 mentioned above, interferes the beam IB with itself after which the beam is received by a photodetector PD. Additional optics (not shown) may be included to provide separate beams in case more than one wavelength is created by the radiation source RSO. The photodetector may be a single element, or it may comprise a number of pixels, if desired. The photodetector may comprise a sensor array.

The diverting optics, which in this example comprises the spot mirror SM, may also serve to block zero order radiation reflected from the mark, so that the information-carrying beam IB comprises only higher order diffracted radiation from the mark AM (this is not essential to the measurement, but improves signal to noise ratios).

SRI Intensity signals SSI are supplied to a processing unit PU. By a combination of optical processing in the self-referencing interferometer SRI and computational processing in the unit PU, values for X- and Y-position on the substrate relative to a reference frame are output.

A single measurement of the type illustrated only fixes the position of the mark within a certain range corresponding to one pitch of the mark. Coarser measurement techniques are used in conjunction with this to identify which period of a sine wave is the one containing the marked position. The same process at coarser and/or finer levels are repeated at different wavelengths for increased accuracy and/or for robust detection of the mark irrespective of the materials from which the mark is made, and materials on and/or below which the mark is provided. Improvements in performing and processing such multiple wavelength measurements are disclosed below.

In the context of wafer alignment, the following approaches are in use or have been proposed to correct the mark position for mark asymmetry (asymmetry in the alignment mark which results in a position error or offset): OCW (Optimal Color Weighing-described in more detail in US publication US2019/094721 A1 which is incorporated herein by reference), OCIW (Optimal Color and Intensity Weighing—described in more detail in PCT publication WO 2017032534 A2) and WAMM (Wafer Alignment Model Mapping—described in more detail in PCT publications WO 2019001871 A1 and WO 2017060054 A1).

Using the example of OCW, in OCW a least squares optimization is performed on alignment model fit coefficients X, in terms of a set of weights w̅ comprising a weight for each of the colors. These weights w̅ are considered optimal when they minimize the difference between alignment and overlay metrology y̅; i.e., the optimization finds the weights w̅ which best satisfies:

$$X \overline{w} = \overline{y}$$

In each of these prior art methods, training to reference overlay data is needed or desired. Other methods may rely on specific assumptions being made on the spatial distribution of the mark-deformation over the wafer. This means that these corrections can only be accurately performed if sufficient reference data is available and if the process variations in the reference data are representative of the variations that need to be corrected. This reference data may be measured by a reference sensor, e.g. hindsight overlay data, such as used in the OCW example just presented. This overlay metrology data is used as a reference in feedback mode: after a wafer has been exposed, the resultant measurement error is observed in hindsight via overlay metrology and corrected for in a future exposure.

There are important drawbacks to using overlay metrology in this way. For example, overlay metrology is expensive, not all exposed wafers are typically measured, measurements take place a relatively long time after exposure such that corrections may be out-of-date by the time they are applied, and overlay metrology also suffers from very similar mark deformation errors and is therefore an imperfect reference.

To address this issue, the multi-color lowest residuals (MCLR) method has been devised, as described in WO2022184405A1. This describes a method of correcting for mark asymmetry using only alignment data, e.g., without relying on overlay metrology feedback. The described method is based on an observed correlation between wafer alignment model residuals (the difference between measured alignment data and the alignment model fitted to the alignment data) and overlay performance. Due to mark asymmetry, each color measures a slightly different wafer shape, and the color which best fits the model may be chosen as the recipe color. This concept may be extended to determine a color weighting for multiple colors, in a manner similar to OCW, but without reliance on reference overlay data. For the avoidance of doubt, all references to “a color” in this disclosure should be understood to encompass (and be shorthand for) a particular wavelength and polarization combination.

The goal of the described MCLR method is to determine a set of color weights which minimizes the alignment model residuals. The specific illustrative method described below determines this set of color weights by performing a linear least squares optimization of the model residuals for each measurement. However, it should be appreciated that this is only one optimization option and alternative optimization methods may be performed instead. For instance by including a regularization term in the optimization based on an L1 norm.

The method comprises obtaining alignment data comprising per-color alignment values (i.e., there are multiple alignment values, one per color, for each alignment mark). The model residuals may be calculated on each alignment mark and for each color by fitting the measurements per color with an alignment model, and recording the fit residuals. The alignment model may be any suitable alignment model used for alignment modeling. The fit residuals can be represented as a residual matrix R, with each element comprising a residual

$${r}_{m}^{( n )}$$

on alignment mark index m (1−M) and color channel n (1−N):

$$R = [ \begin{matrix}{r}_{1}^{( 1 )} & {r}_{1}^{( 2 )} & ⋯ & {r}_{1}^{( N )} \\ {r}_{2}^{( 1 )} & {r}_{2}^{( 2 )} & ⋯ & {r}_{2}^{( N )} \\ {r}_{3}^{( 1 )} & {r}_{3}^{( 2 )} & ⋯ & {r}_{2}^{( N )} \\ ⋮ & ⋮ & ⋱ & ⋮ \\ {r}_{M}^{( 1 )} & {r}_{M}^{( 2 )} & ⋯ & {r}_{M}^{( N )}\end{matrix} ]$$

The residuals may be calculated over multiple wafers and stacked vertically in R.

The goal of the algorithm is to find a set of color weights w̅=[w⁽¹⁾ w⁽²⁾ . . . w^{(N)}]^{T} which minimize the residuals R (e.g., in a least squares sense), i.e., to obtain:

$$R \overline{w} = \overline{0}$$

$$[ \begin{matrix}{r}_{1}^{( 1 )} & {r}_{1}^{( 2 )} & ⋯ & {r}_{1}^{( N )} \\ {r}_{2}^{( 1 )} & {r}_{2}^{( 2 )} & ⋯ & {r}_{2}^{( N )} \\ {r}_{3}^{( 1 )} & {r}_{3}^{( 2 )} & ⋯ & {r}_{2}^{( N )} \\ ⋮ & ⋮ & ⋱ & ⋮ \\ {r}_{M}^{( 1 )} & {r}_{M}^{( 2 )} & ⋯ & {r}_{M}^{( N )}\end{matrix} ] [ \begin{matrix}{w}^{( 1 )} \\ {w}^{( 2 )} \\ ⋮ \\ {w}^{( N )}\end{matrix} ] = [ \begin{matrix}0 \\ 0 \\ ⋮ \\ 0\end{matrix} ]$$

This system of equations can be solved, for example, via linear least squares regression under the additional constraint that the sum of color weights must equal 1:

$${\sum }_{n = 1}^{N} {w}^{( n )} = 1$$

This constraint ensures that the determined aligned position correction is invariant to a translation in all of the colors, and also to avoid the trivial solution where all weights equal 0.

Once this system of equations is solved, applying the resulting optimal weights w to the alignment data will result in minimal model residuals (e.g., minimal root sum square/root mean square of model residuals) over the (set of) wafer(s) considered in the input. The weighting can be applied to alignment data so as to correct the alignment data for mark asymmetry when determining the alignment grid for future exposures.

The MCLR method may be implemented as an external training algorithm in a similar manner to OCW. Alignment data from one or more wafers may be used as training data so as to determine a set of color weights, which can then be applied on one or more (future) wafers. However, the reliance on only alignment data without the need for reference overlay data also means that same method can be used to perform a per-wafer inline alignment correction; e.g., within a scanner or separate alignment station. Subsequent to all alignment marks having been measured (e.g., within a measurement stage of a twin stage system or a stand-alone alignment station), but before the wafer has been transferred to an exposure stage or exposure station, the proposed method may be used to determine a set of color weights which minimizes the model residuals for each wafer on a per-wafer basis. In this manner, the alignment grid for each wafer may be corrected with a set of optimal color weights specifically determined for that wafer.

In general, the set of color weights obtained using the methods described above will comprise non-zero values for every color. For example, some alignment sensors can measure with up to 24 illumination settings (e.g., 12 wavelengths and two polarizations), and as such the methods disclosed herein may determine 24 color weights.

In an embodiment, it may be advantageous to place a restriction on the number of color weights used in the solution, e.g., to restrict the number of colors used for a measurement (e.g., up to a maximum of 4, 5, 6 or 7 colors), thereby determining a preferred subset of said plurality of illumination settings. Advantages of such an embodiment comprise more robustness against overfitting on outliers in the training data, and less strict requirements on the future wafers on which the recipe will be applied, since all colors with non-zero weight must also be valid (e.g., sufficient signal strength).

A first approach for reducing the number of color weights (which may be applied on its own or in combination with other such methods described herein) may comprise applying appropriate thresholds to exclude colors with very small associated weights, and/or remove colors that do not contribute significantly to the result (e.g., colors with an associated weight below a threshold may be excluded).

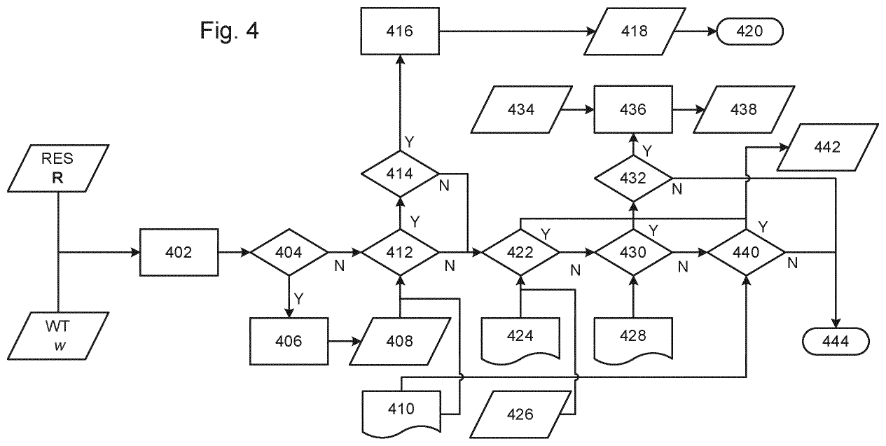

FIG. 4 is a flowchart describing a method which may be used to reduce the number of colors (e.g., to determine a set of enabled colors for metrology as a subset of available colors). This describes a method to remove colors via a backward stepwise selection of predictors. Another approach would be to take forward stepwise selection, or a combination of both.

At step 402 a color impact metric and current performance metric is determined from residuals (RES) R and weights (WT) w. The current performance may be determined from the regression error (e.g., the square root of the regression error: \sqrt{(Rw̅)^{T}(Rw̅)}). The color impact metric may be constructed by multiplying each color (column) of the residual matrix by the corresponding color weight. Based on this, the RMS (or other suitable statistical measure) per color can be determined, resulting in a color impact vector with a value per color.

The method described by the flowchart can be repeated over a number of runs, e.g., potentially removing a color at a time. At step 404, it is determined whether this is a first run and if so the current performance metric determined in the previous step is used to initialize 406 a start performance metric 408. At step 412, it is determined whether the difference between the current performance metric and start performance metric 408 is outside of a performance threshold 410: if so it is then determined 414 whether the previous run resulted in color being removed based on performance. If so, the algorithm reverts 416 to the weights from the previous run 418 and ends 420 with these weights and present enabled colors.

If either of step 412, 414 are negative, at step 422, it is determined whether the present number 426 of enabled colors is greater than a designated maximum 424 number of enabled colors. If not, at step 430, it is determined whether any of the weights has a magnitude below a minimum weight threshold 428. If not, at step 440 it is determined whether the difference between the current performance metric and start performance metric 408 is within the performance threshold 410. If not, the process ends 444 with the current weights and enabled colors.

If, for any of steps 422, 430, 440, the determination is yes, than the present weights for this run are stored 442 and at step 432 it is determined whether the number of colors is greater than 1. If not, the process ends 444 with the current weights. If so, based on the present enabled colors 434, the color with the lowest associated color impact is removed, to determine an updated set of enabled colors 438. A further run can then be performed based on the updated enabled colors 438 and its associated weights 442.

Another approach to reduce the number of colors may comprise a brute force approach in which all color combinations are considered and the best combination (preferred subset) selected (e.g., the combination which satisfies all conditions). More specifically the method may comprise calculate the solution for each possible set of color weights, starting from each single color and stepwise adding a color and assessing for each combination. As such, this may comprise beginning with all 1-color solutions, then all 2-color solutions, then all 3-color solutions, up to all color solutions. The optimal solution may be the solution meeting a certain performance threshold using the fewest number of colors.

The above methods describe minimization of model residuals with respect to a single layer or reference layer (e.g., L0), as is typically done in alignment. In many cases this will indeed yield the best result. However, in some cases, minimizing a point-to-point difference or delta of model residuals between two particular layers (e.g., overlay of two particular layers) may be preferred, even when this results in higher residuals for each of these layers with respect to a bottom/reference layer.

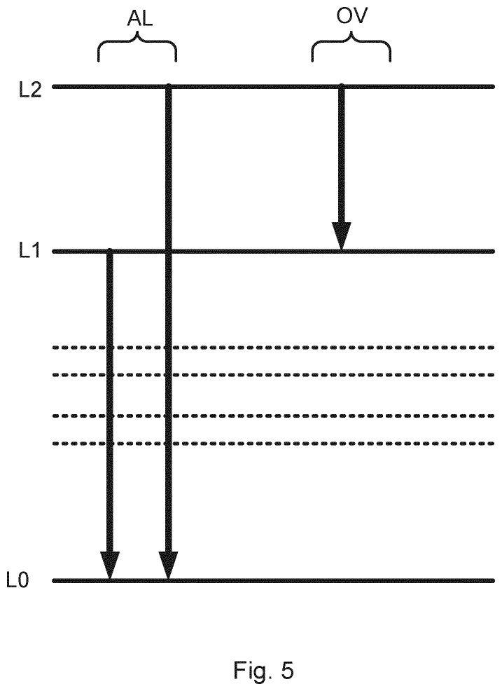

FIG. 5 conceptually illustrates an example of indirect alignment, where two layers L1 and L2 both align AL back to the same bottom or reference layer L0, while device yield is mainly dependent on the overlay OV L2-L1 between layer L1 and layer L2 (and not with respect to L0). The aforementioned MCLR method will minimize residuals between layer L1 and reference layer L0, and between layer L2 and reference layer L0. The proposed method will aim to determine one or more sets of weights which minimize the residual difference between layers L1 and L2. Overlay between layer L1 and layer L2 may be near optimal when the alignment model residuals of layer L2 match the alignment model residuals of layer L1. This effectively means that the same mistake is repeated in both layers, cancelling out the errors between the layers such that there is minimal overlay between layer L1 and layer L2. As before, this method may use only alignment data, e.g., to determine alignment data residuals with respect to a fitted alignment model; no post exposure overlay data is required.

There are a number of different implementations for achieving this. In one embodiment, the color weight recipe of bottom layer L1 may be fixed such that only the color weights of the top layer L2 are allowed to change during the optimization. Alternatively, it may be that the color weights of both layers may be allowed to change. In one such embodiment, a common color recipe is determined for the two layers. In another such embodiment, each of the two layers may be allowed to have a respective different set of optimized weights which are not necessarily the same. If the bottom layer recipe is also allowed to change, a larger performance gain may be achieved, although this is potentially at the cost of poorer performance for the bottom layer.

As such, a method for determining at least one set of correction weights to correct metrology data is disclosed. The method comprises obtaining first metrology data relating to a first set of illumination settings of measurement radiation used to perform a measurement of a first layer; fitting the first metrology data to a model for representing the metrology data and determining a first set of fit residuals as the residuals of said first metrology data with respect to the model; obtaining second metrology data relating to a second set of illumination settings of measurement radiation used to perform a measurement of a second layer, where each illumination setting of said first set of illumination settings and said second set of illumination settings comprises a different wavelength, polarization or combination thereof; fitting the second metrology data to a model for representing the metrology data and determining a second set of fit residuals as the residuals of said second metrology data with respect to the model; and determining said at least one set of correction weights as at least one set of correction weights which minimize a difference between said first set of fit residuals and said second set of fit residuals.

In particular, the first metrology data may comprise first alignment data from (optionally) a multi-color alignment measurement of the first layer and the second metrology data may comprise second alignment data from a multi-color alignment measurement of the second layer. The first metrology data and second metrology data may be obtained from a single alignment sensor (e.g., as part of a single lithography apparatus (scanner) or stand-alone alignment station), or from different alignment sensors (e.g., in respective different lithography apparatuses or stand-alone alignment stations, or possibly within a single lithography apparatus).

The first set of illumination settings and said second set of illumination settings may comprise a common set of illumination settings. However, this is not essential, and at least some embodiments may use different respective illumination settings for the first metrology data and second metrology data (although of course the latter is not possible for the embodiment described below where the first and second layers are optimized with common weights). Furthermore, while all embodiments require the second measurement data of the second layer (top layer) to relate to a plurality of illumination settings (e.g., to have been measured with two or more measurement settings), the embodiment where only the top layer weights are optimized does not require the first metrology data (first layer) to relate to a plurality of illumination settings; e.g., this layer may be measured using only a single illumination setting as it is not being optimized.

In all cases, the same alignment marks (the same number of marks at a common set of measurement locations) should be measured for each of the two layers. If not, the optimization may be performed only on the intersection (common measurement points) of the two sets of measurements. This is because a point-to-point delta can only be calculated at each point where both measurements (first layer and second layer) are available. If there are points where one measurement is missing, that point cannot be included in the point-to-point delta. The intersection of both layer measurements means the set of points where both the first layer and second layer measurements are available and valid.

Each of these methods will now be individually described.

### Optimizing Only Top Layer Weights

The layer-to-layer difference (delta) may be optimized by applying the MCLR algorithm (e.g., as has already been described and disclosed in WO2022184405A1) to the delta of the residuals per color of a second layer (or top layer) L2, and the fixed residuals of a first layer L1. Note that the terms “first layer” and “second layer” are used simply to distinguish the layers and describe a relative order (i.e., the first layer is exposed before the second layer). However, there may be one or more layers exposed on the substrate before the first layer, and/or also possibly between exposure of the first layer and second layer.

Such a method may comprise performing an optimization for the second layer correction weights w_{L2}; e.g., by finding the second layer correction weights w_{L2} which minimize the residual difference between a second set of fit residuals (second layer residuals) and a vector comprising a first set of fit residuals (first layer residuals):

$${W}_{L 2} = arg {min}_{{w}_{L 2}} {‖ ( {R}_{L 2} - {R}_{L 1} ) \cdot {W}_{L 2}^{T} ‖}^{2}$$

where R_{L2} is a matrix comprising residuals per mark and per color of second layer L2 and R_{L1} is a vector with residuals per mark of first layer L1, but not per color. Vector R_{L1} may be determined as:

$${R}_{L 1} = {R}_{L 1} \cdot {w}_{L 1}^{T}$$

where R_{L1} is a matrix with residuals per mark and per color of first layer L1 and w_{L1} are the first layer weights (e.g., as determined in a previous optimization). In each case the superscript T indicates a transpose matrix.

In this embodiment, the basic MCLR method is unchanged and can be performed as has been described. The difference is the input (i.e., the residual difference rather than single layer residuals).

Optimizing Both First and Second Layers with Common Weights

In this method, a common set of correction weights w_{L1,L2} for both the first metrology data (first layer) and second metrology data (second layer) are determined, i.e., the weights are co-optimized with the constraint that they are the same for the two layers. In this embodiment, the MCLR method is performed on the residual difference between the second set of fit residuals of the second layer R_{L2} and the first set of fit residuals of the first layer R_{L1}. In each case per color residuals may be used. Matrices R_{L1} and R_{L2} should have the same size. As such, the data in Matrices R_{L1} and R_{L2} may represent residuals from the same mark locations (in the rows) measured in layers L1 and L2 respectively, and measured with the same set of colors (in the columns). The optimization may minimize the following:

$${w}_{L 1 , L 2} = arg {min}_{{w}_{L 1 , L 2}} {‖ ( {R}_{L 2} - {R}_{L 1} ) \cdot {W}_{L 1 , L 2}^{T} ‖}^{2}$$

As with the previous embodiment, the basic MCLR method is unchanged and can be performed as has been described. The difference is the input; i.e., the residual difference (now per color for both layers) rather than single layer residuals.

Optimizing Both First and Second Layers with Independent Weights

If both layers are allowed to obtain independent weights, then the quadratic equality constrained problem that minimizes their residual difference may be solved in terms of first layer correction weights w_{L1} for the first metrology data/first layer and second layer correction weights w_{L2} for the second metrology data/second layer. For example, the cost function to be solved may comprise:

$$( {W}_{L 1 ,} {W}_{L 2} ) = arg {min}_{{w}_{L 1 ,} {w}_{L 2}} {‖ {R}_{L 1} \cdot {w}_{L 1}^{T} - {R}_{L 2} \cdot {w}_{L 2}^{T} ‖}^{2}$$

This can no longer be solved using the MCLR method as has been described (e.g., with modified input). Instead the MCLR method itself may be modified to solve for two sets of weights. The solution may be found by rewriting the problem as an unconstrained problem which can be solved via, e.g., subspace modeling or quadratic optimization/quadratic programming. These are only examples and there are many such mathematical techniques and approaches for solving such a cost function, which are well known to the skilled person and as such will not be described further here.

Additionally, to prevent the solution from deviating too far from a good solution, a prior for the weights may be imposed, such that only small deviations from the prior are allowed. This avoids the case where the layer weighted residuals for both layers become very large but equal such that their delta is still small. The regular MCLR weights (e.g., a first set of initial weights w_{L1,L0} and a second set of initial weights w_{L2,L0}) which sequentially optimize the first layer and second layer (e.g., toward residuals of zero) may be used for such a prior. In addition, a regularization term

$$λ {‖ {w}_{L 1}^{T} ‖}^{2} , λ {‖ {w}_{L 2}^{T} ‖}^{2} ,$$

for each set of weights may be imposed, where the size of the regularization term λ describes the amount of regularization. As such, λ=0 would mean no regularization such that the solution is the same as in the previous section. A large value for the regularization term λ will force the solution at or very near the initial weights w_{L1,L0} and w_{L2,L0}. Such a regularization term may favor simple solutions and/or smaller weights for example. Note that a similar regularization term may be used in the other embodiments above (in each case there is only one set of weight so only a single regularization term would be required).

As such, in an embodiment, the cost function may be:

$$( {w}_{L 1 ,} {w}_{L 2} ) = arg {min}_{{w}_{L 1 ,} {w}_{L 2}} {‖ {R}_{L 1} \cdot ( {W}_{L 1 , L 0}^{T} + {W}_{L 1}^{T} ) - {R}_{L 2} \cdot ( {W}_{L 2 , L 0}^{T} + {W}_{L 2}^{T} ) ‖}^{2} + λ {‖ {W}_{L 1}^{T} ‖}^{2} + λ {‖ {W}_{L 2}^{T} ‖}^{2}$$

$${w}_{L 1 , L 0} = arg {min}_{w} {‖ {R}_{L 1} \cdot {w}^{T} ‖}^{2}$$

$${w}_{L 1 , L 0} = arg {min}_{w} {‖ {R}_{L 2} \cdot {w}^{T} ‖}^{2}$$

Now, since the prior solutions w_{L1,L0}, and w_{L2,L0} already sum to 1, the deviations to those priors may be constrained to sum to 0:

$$\sum {w}_{L 1}^{T} = \sum {w}_{L 2}^{T} = 0$$

Any of the embodiments disclosed herein may disclose any of the color reduction methods described herein.

Further methods will now be described, applying similar ideas as described above to overlay (more generally parameter of interest) trained OCW techniques, which use reference metrology data (e.g., overlay data) to train the recipe. Overlay trained OCW is described above, and aims to find a weighting, which minimizes an error or difference between the weighted alignment data and corresponding reference metrology data or overlay data from the same substrate. Typically, color weight recipes are optimized sequentially and independently for each layer in the stack. When indirect alignment is used, however, this may not be optimal.

In both direct and indirect alignment cases, the overlay between layer L2 and layer L1 is influenced by the exposure of layer L2 (position of the top grating(s) of overlay target(s)) and also the exposure of layer L1 (position of the bottom grating(s) of overlay target(s)). Therefore, a change in the alignment recipe for layer L1 can affect overlay L2-L1, in addition to a change in the alignment recipe for layer L2. The main difference however between direct and indirect alignment is that, in direct alignment, any change in layer L1 alignment also changes the positions of the newly printed alignment marks in L1 (as seen from layer L2). Therefore, any change in layer L1 can be measured and corrected for at layer L2: i.e., layer L2 can observe and follow the change in L1. In indirect alignment, a change of L1 alignment is not observed on the next layer, because layer L2 still references to the same alignment marks in reference layer L0, which are unchanged by the exposure of layer L1. As such, layer L2 cannot see and cannot follow any change in layer L1; more generally, later layers cannot follow changes in any preceding layer (after layer L0).

For this reason, in indirect alignment, it is important to consider the impact of both layer L1 alignment and layer L2 alignment. A change in the L1 alignment recipe will require a corresponding change in the L2 alignment to follow the change in layer L1 and maintain the L2-L1 overlay error within specification.

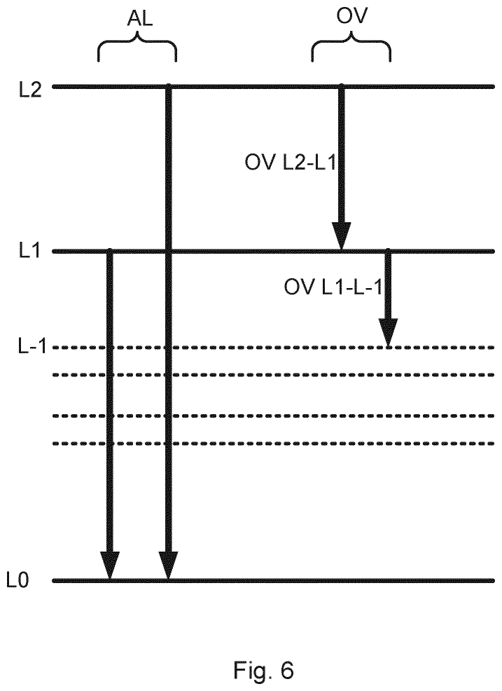

A multi-layer co-determination or co-optimization of color weight recipes or multi-layer OCW will now be described. It is proposed to co-optimize indirect alignment of (at least) two layers L2, L1 (e.g., with respect to a reference layer L0), to minimize overlay L2-L1, while ensuring that overlay L1-L−1 to a preceding layer (e.g., an immediately preceding layer such that layer L−1 immediately precedes L1) is maintained within specification. This overlay is also shown in FIG. 6, which illustrates a similar arrangement to that of FIG. 5, but with overlay L2-L1 and overlay L1-L−1 explicitly shown. Such an approach may be particularly beneficial where the tolerance for overlay L2-L1 is tighter than for overlay L1-L−1. In this manner, overlay L2-L1 can be significantly improved. It can be appreciated that, while this improvement will be at the cost of slightly poorer overlay performance for overlay L1-L−1, this will be acceptable provided that this overlay is still maintained within specification.

In fact, in a typical indirect alignment tree, many layers all align back to the same reference layer. In such a case, each layer has an indirect influence on the overlay L2-L1, because L2-L1 overlay is impacted by L1 alignment, and L1 alignment is impacted by L−1 alignment, L−1 alignment impacted by L−2 alignment and so on.

For indirect alignment, it is not optimal to sequentially optimize the color weight recipe per layer, i.e., optimizing layer L1 first, and then layer L2 while maintaining layer L1 fixed. Instead, better performance may be achieved by co-optimizing both layers at the same time, to obtain optimal overlay L2-L1.

Co-optimization of the two layers requires preparation steps to “decorrect” the active alignment corrections for each of layer L2 and layer L1 (e.g., a first set of active weights and a second set of active weights). Active alignment X_{Lx} for layer Lx (where x is 1 and 2 in the example below) is the weighted alignment data for that layer according to the present or active recipe. As such:

$${X}_{L x} = {w}_{L x} {X}_{L x} = {\sum }_{i = 1}^{N} {w}_{i} \cdot X ( {λ}_{i} )$$

where w_{Lx} is the weighting for layer Lx, X_{Lx} is the measured alignment data for layer Lx, wᵢ is the weight per-color (indexed i) and X(λᵢ) is the per-color alignment data. In the context of this disclosure, decorrect may comprise removing corrections such as the corrections performed during alignment (i.e., removing the alignment corrections). As such, decorrected overlay data may comprise overlay data for which the previously applied alignment corrections of each layer are removed.

In a first step, the measured overlay L2-L1 y_{L2-L1} should be decorrected for the active alignment of layer L2 (active L2 corrections are removed), to obtain decorrected overlay L2-L1 y_{L2-L1,dL2}. This simulates “undoing” the alignment corrections to the top layer structures (e.g., top gratings of an overlay target):

$${y}_{L 2 - L 1 , dL 2} = {y}_{L 2 - L 1} + {X}_{L 2} = {y}_{L 2 - L 1} + {X}_{L 2} \cdot {w}_{L 2}$$

The resulting decorrected overlay y_{L2-L1,dL2} should then be further decorrected for the active alignment of layer L1 (to obtain “double-decorrected” overlay y_{L2-L1,dL2,dL1}). This simulates “undoing” also the alignment corrections to the bottom layer. The decorrection in this step should be performed with a sign flip, because it is being applied to the bottom grating:

$${y}_{L 2 - L 1 , dL 2 , dL 1} = {y}_{L 2 - L 1 , dL 2} + ( - {X}_{L 1} ) = {y}_{L 2 - L 1} + {X}_{L 2} \cdot {w}_{L 2} - {X}_{L 1} \cdot {w}_{L 1}$$

To simulate the impact of new (potentially better) alignment recipes at layer L2 and layer L1, both recipes may be applied to the double-decorrected overlay to obtain new overlay data y_{L2-L1,new}:

$${y}_{L 2 - L 1 , new} = {y}_{L 2 - L 1 , dL 2 , dL 1} - {X}_{L 2} \cdot {w}_{L 2 , new} + {X}_{L 1} \cdot {w}_{L 1 , new}$$

where w_{L2,new}, w_{L1,new} are new recipes for layer L2 and layer L1 respectively.

The optimized color weight recipes w_{L2,opt} w_{L1,opt} for layer L2 and layer L1 can be found simultaneously in a single optimization, e.g., by concatenating the measured alignment and weights:

$${w}_{L 1 , L 2 , opt} ≡ [ \begin{matrix}{w}_{L 2 , opt} \\ {w}_{L 1 , opt}\end{matrix} ] , {x}_{L 2 , L 1} ≡ [ {x}_{L 2} - {x}_{L 1} ]$$

$${w}_{L 1 , L 2 , opt} = {arg min}_{{w}_{L 1 , L 2 , opt}} {‖ {y}_{L 2 - L 1 , dL 2 , dL 1} - {X}_{L 2 , L 1} \cdot {w}_{L 1 , L 2 , opt} ‖}^{2}$$

$$( {w}_{L 2 , opt} , {w}_{L 1 , opt} ) = {arg min}_{{w}_{L 2 , opt} , {w}_{L 1 , opt}} {‖ {y}_{L 2 - L 1 , dL 2 , dL 1} - {X}_{L 2} \cdot {w}_{L 2 , opt} + {X}_{L 1} \cdot {w}_{L 1 , opt} ‖}^{2}$$

As before, both the weights w_{L2,opt}, w_{L1,opt} may be constrained to sum to 1 to prevent trivial solutions.

Optionally, the method just described may be regularized to penalize solutions which for which the layer L1 weights w_{L1,opt} deviate too far from a prior weight recipe w_{L1,prior}. While the optimization routine as just described will find the optimized combination of weights for layers L2 and L1, it does not take into account overlay L1-L−1, which is of course impacted by the weighting applied to layer L1. Allowing the optimization to be free to choose any weights for layer L1 (to optimize L2-L1 overlay), may result in overlay L1-L−1 becoming severely impacted (e.g., to be out of specification). To solve this issue, a known good prior recipe for layer L1 can be included into the cost function (e.g., as part of a regularization term), and the solution can be constrained such that the new weights at layer L1 remain close to the prior recipe. In this case, the overlay L1-L−1 may still deteriorate slightly to improve overlay L2-L1, but it will not be allowed to stray too far from the initial recipe.

The prior solution can be included via a regularization penalty which penalizes large deviations of the new recipe with respect to the prior recipe w_{L1,prior}:

$$( {w}_{L 2 , opt} , {w}_{L 1 , opt} ) = {arg min}_{{w}_{L 2 , opt} , {w}_{L 1 , opt}} {‖ {y}_{L 2 - L 1 , dL 2 , dL 1} - {X}_{L 2} \cdot {w}_{L 2 , opt} + {X}_{L 1} \cdot {w}_{L 1 , opt} ‖}^{2} + {λ}_{L 1} {‖ {w}_{L 1 , opt} - {w}_{L 1 , prior} ‖}^{2}$$

where λ_{L1} is a regularization parameter. This regularization parameter provides a trade-off between overlay L2-L1 and overlay L1-L−1 (i.e., determines by how much overlay L1-L−1 is allowed to deteriorate in order to improve overlay L2-L1). As such, λ_{L1} may be tuned depending on the respective specifications of overlay L2-L1 and/or overlay L1-L−1.

The prior set of correction weights may be determined using a conventional OCW recipe training (single layer optimization) for that layer, e.g., for layer L1 in this case, or else it may use the results of a previous optimization to optimize said parameter of interest between L1 and a layer preceding said first layer (e.g., layer L−1), as will be described.

In a typical indirect alignment use-case, many consecutive layers L3, L2, L1, L−1, L−2 . . . all align back to the same bottom layer L0, while overlay is critical between each consecutive layer (L3-L2, L2-L1, L1-L−1, L−1-L−2 . . . ). The co-optimization routine described so far can be applied sequentially to each layer pair, e.g., while constraining the solution of the bottom layer close to a previous solution via a regularization penalty as described.

As an example, starting at layer pair L−1-L−2, the weights for layer L−1 and L−2 may be optimized as has been described; e.g.,:

$$( {w}_{L - 1 , opt} , {w}_{L - 2 , opt} ) = {arg min}_{{w}_{L - 1 , opt} , {w}_{L - 2 , opt}} {‖ {y}_{L - 1 - L - 2 , dL - 1 , dL - 2} - {X}_{L - 1} \cdot {w}_{L - 1 , opt} + {X}_{L - 2} \cdot {w}_{L - 2 , opt} ‖}^{2} + {λ}_{L - 2} {‖ {w}_{L - 2 , opt} - {w}_{L - 2 , prior} ‖}^{2}$$

The found weights for layer L−1 will then become the prior for optimization of the next layer pair L1-L−1; i.e., weight w_{L-1,opt} may be used as the prior w_{L-1,prior}. This optimization finds a better recipe for layer L−1, and the prior for L1, etc.; e.g.:

$$( {w}_{L 1 , opt} , {w}_{L - 1 , opt} ) = {arg min}_{{w}_{L 1 , opt} , {w}_{L - 1 , opt}} {‖ {y}_{L 1 - L - 1 , dL 1 , dL - 1} - {X}_{L 1} \cdot {w}_{L 1 , opt} + {X}_{L - 1} \cdot {w}_{L - 1 , opt} ‖}^{2} + {λ}_{L - 1} {‖ {w}_{L - 1 , opt} - {w}_{L - 1 , prior} ‖}^{2} ,$$

$$where {w}_{L - 1 , opt} = {w}_{L - 1 , prior}$$

This can be repeated for each successive layer, e.g., the next layer can be optimized using the cost function for overlay L2-L1 already given, with w_{L1,opt} just determined being used for w_{L1,prior}.

In each step, the regularization parameter λ_{Lx} can be tuned based on the criticality of the overlay of that layer pair. For example, if the overlay L1-L−1 is not very critical, the regularization parameter λ_{L1} for the next step regularization can be relaxed so that the new recipe for layer L1 can deviate a bit more from the prior. This could result in slightly deteriorated overlay L1-L−1 (which is not critical) and improved overlay L2-L1.

Co-optimization is especially useful for indirect alignment because the change in, e.g., layer L1 is not observed from layer L2 since layer L2 does not align to layer L1. However, it can be appreciated that the concepts disclosed herein are applicable to direct alignment. However, the additional value of such a method for direct alignment it is not expected to be great because the change in layer L1 can already be observed and followed by layer L2.

The concepts disclosed herein may be generalized to determining a set of color weights (or illumination setting weights, where an illumination setting is a combination of a measurement wavelength and polarization) for correction of multiple color/illumination setting metrology data by minimizing a model residual delta between two layers in terms of the weights, the model residuals being obtained from a fitting of each set of metrology data to a model for representing the metrology data.

While specific embodiments of the invention have been described above, it will be appreciated that the invention may be practiced otherwise than as described.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

Aspects of the invention are set out in the clauses below.
1. A method for determining at least one set of correction weights to correct metrology data; the method comprising: obtaining first metrology data relating to a first set of illumination settings of measurement radiation used to perform a measurement of a first layer; fitting the first metrology data to a model for representing the metrology data and determining a first set of fit residuals as the residuals of said first metrology data with respect to the model; obtaining second metrology data relating to a second set of illumination settings of measurement radiation used to perform a measurement of a second layer, said second set of illumination settings comprising a plurality of illumination settings, where each illumination setting comprises a different wavelength, polarization or combination thereof; fitting the second metrology data to a model for representing the metrology data and determining a second set of fit residuals as the residuals of said second metrology data with respect to the model; and determining said at least one set of correction weights as at least one set of correction weights which minimize a difference between said first set of fit residuals and said second set of fit residuals.
2. A method according to clause 1, wherein each said fitting step comprising fitting the respective first metrology data and second metrology data per illumination setting with said model, and recording the fit residuals for each illumination setting.
3. A method according to clause 1 or 2, wherein said determining said at least one set of correction weights comprises determining a single set of correction weights.
4. A method according to clause 3 wherein said single set of correction weights comprise second layer correction weights for correcting only the second set of metrology data, wherein said second layer comprises a top layer and said first layer comprises a layer below the second layer.
5. A method according to clause 4, wherein said determining step comprises performing an optimization of the second layer correction weights such that they minimize a difference between said second set of fit residuals and a residual vector related to said first set of residual data.
6. A method according to clause 5, wherein said residual vector comprises a set of fit residuals per target or mark, determined from said first set of residual data and fixed first layer correction weights.
7. A method according to clause 6, comprising performing an initial optimization on said first metrology data only to determine said first set of residual data and fixed first layer correction weights.
8. A method according to clause 5, 6, or 7, wherein said second set of fit residuals is comprised in a residual matrix comprising said metrology data arranged per target or mark in a first dimension and per illumination condition in a second dimension.
9. A method according to clause 3, wherein said single set of correction weights comprises a common set of correction weights for correcting each of said first set of metrology data and said second set of metrology data.
10. A method according to clause 9, wherein said determining step comprises performing an optimization of the common set of correction weights such that they minimize a difference between a first residual matrix comprising said first metrology data arranged per target or mark in a first dimension and per illumination condition in a second dimension and a second residual matrix comprising said second metrology data arranged per target or mark in the first dimension and per illumination condition in the second dimension.
11. A method according to clause 1 or 2, wherein said determining said at least one set of correction weights comprises determining first layer correction weights for correcting said first metrology data and second layer correction weights for correcting said second metrology data.
12. A method according to clause 11, wherein said determining step comprises performing a co-optimization of said first layer correction weights and said second layer correction weights such that they minimize a difference of said first set of fit residuals weighted by said first layer correction weights and said second set of fit residuals weighted by said second layer correction weights.
13. A method according to clause 12, comprising imposing a prior which minimize a magnitude of said first set of fit residuals weighted by said first layer correction weights and a magnitude of said second set of fit residuals weighted by said second layer correction weights.
14. A method according to clause 13, wherein said prior is based on a first set of initial weights which optimize the first set of fit residuals towards zero and a second set of initial weights which optimize the second set of fit residuals toward zero.
15. A method according to clause 14, comprising performing a first initial optimization on said first metrology data to obtain said first set of initial weights and a second initial optimization on said second metrology data to obtain said second set of initial weights.
16. A method according to any of clauses 11 to 15, wherein said first set of fit residuals are comprised in a first residual matrix comprising said metrology data arranged per target or mark in a first dimension and per illumination condition in a second dimension and said second set of fit residuals are comprised in a second residual matrix comprising said metrology data arranged per target or mark in the first dimension and per illumination condition in the second dimension.
17. A method according to any preceding clause, wherein said first set of illumination settings comprises a plurality of illumination settings, where each illumination setting comprises a different wavelength, polarization or combination thereof.
18. A method according to any preceding clause, wherein said determining step uses a regularization which favors smaller weight values for said at least one set of weights.
19. A method according to any preceding clause, wherein said determining step uses at least one least squares optimization.
20. A method according to any preceding clause, wherein each set of said at least one set of correction weights comprise a correction weight for each of said set of illumination settings.
21. A method according to any preceding clause, further comprising determining a preferred subset of said set of illumination settings.
22. A method according to clause 21, wherein said step of determining a preferred subset comprises: evaluating a candidate combination of illumination settings in terms of a performance metric and an impact metric; and removing or adding an illumination setting to said candidate combination of illumination settings based in said performance metric and impact metric.
23. A method according to clause 22, wherein said removing or adding step comprises removing an illumination condition having a lowest impact metric provided that a performance threshold is met to obtain an updated candidate combination of illumination settings.
24. A method according to clause 22 or 23, comprising performing said evaluating and removing or adding steps until said candidate combination of illumination settings comprises a desired number of illumination settings.
25. A method according to clause 21, wherein said step of determining a preferred subset comprises evaluating all possible combinations of illumination settings; and selecting said preferred subset as the combination of illumination settings which meets a performance threshold using the fewest number of illumination settings.
26. A method according to any preceding clause, comprising removing any illumination setting for which the determined correction weight is below a significance threshold.
27. A method according to any preceding clause, wherein said determination step is constrained such that the sum of each set of said at least one set of correction weights equals one.
28. A method according to any preceding clause, wherein said first metrology data and second metrology data each comprises alignment data.
29. A method according to clause 28, comprising applying each set of said at least one set correction weights to a respective alignment measurement of a substrate performed with a plurality of illumination settings to obtain a corrected alignment measurement.
30. A method according to clause 29, comprising performing said alignment measurement.
31. A method according to clause 29 or 30, wherein the method is performed to determine said at least one set of correction weights in an initial training phase using training substrates, said determined at least one set of correction weights being for application to a plurality of subsequent substrates.
32. A method according to clause 29 or 30, wherein said method is performed between performance of an alignment metrology step and a lithographic exposure step; wherein said alignment metrology step is performed to obtain said alignment measurement such that said first alignment data comprises said alignment measurement, and the method further comprises: performing the lithographic exposure step using the alignment measurement as corrected by application of the determined at least one set of correction weights.
33. A method according to clause 32, wherein said at least one set of correction weights are determined individually for each substrate prior to each exposure step.
34. A method according to any of clauses 28 to 33, wherein the method comprises, when an amount of overlay data available reaches a threshold, transitioning to an optimization based on minimizing a difference between said overlay data and said alignment data.
35. A method according to any of clauses 28 to 34, wherein said determining said correction weights comprises performing a co-optimization between said minimizing fit residuals and minimizing the difference between overlay data and said alignment data.
36. A method according to any of clauses 1 to 27, wherein said metrology data comprises overlay data.
37. A method according to any preceding clause, wherein said first set of illumination settings and said second set of illumination settings comprise a common set of illumination settings.
38. A method according to any preceding clause, wherein said first metrology data and said second metrology data each relate to a common set of measurement locations.
39. A computer program comprising program instructions operable to perform the method of any of clauses 1 to 38, when run on a suitable apparatus.
40. A non-transient computer program carrier comprising the computer program of clause 39.
41. A processing system comprising a processor and a storage device comprising the computer program of clause 40.
42. An alignment sensor operable to perform the method of any of clauses 1 to 38.
43. A lithographic apparatus comprising: a patterning device support for supporting a patterning device; a substrate support for supporting a substrate; and the alignment sensor of clause 42.
44. A metrology device operable to perform the method of any of clauses 1 to 38.
45. A method for determining a first set of correction weights for a first layer and a second set of correction weights for a second layer; the method comprising:
obtaining reference metrology data relating to a parameter of interest between said first layer and second layer;
decorrecting said reference metrology data for first metrology corrections performed when exposing said first layer and second metrology corrections performed when exposing said second layer, to obtain decorrected reference metrology data; and
co-determining said first set of correction weights and said second set of correction weights such that they improve said parameter of interest between said first layer and second layer when said first set of correction weights are applied to first metrology data related to the first layer to obtain first weighted metrology data and said second set of correction weights are applied to second metrology data related to the second layer to obtain second weighted metrology data.
46. A method according to clause 45, wherein said co-determining step comprises co-determining said first set of correction weights and said second set of correction weights so as to minimize said decorrected reference metrology data as corrected using said first weighted metrology data and said second weighted metrology data.
47. A method according to clause 45 or 46, wherein:
said first metrology corrections comprise said first metrology data as weighted by a first set of active weights for said first layer; and
said second metrology corrections comprise said second metrology data as weighted by a second set of active weights for said second layer.
48. A method according to any of clauses 45 to 47, wherein said co-determining step comprises constraining the co-determination to penalize solutions for which said first set of correction weights deviates significantly from a prior first set of correction weights.
49. A method according to clause 48, wherein said constraining step is applied via a regularization term comprising a regularization parameter, and said method comprises selecting and/or tuning said regularization parameter based on a specification for said parameter of interest between said first layer and second layer and/or parameter of interest between a preceding layer and said first layer.
50. A method according to clause 48 or 49, wherein said prior first set of correction weights comprises a set of correction weights determined in a previous optimization, to optimize said parameter of interest between said first layer and a layer preceding said first layer.
51. A method according to clause 50, comprising performing said method to optimize successive pairs of sets of correction weights for successive pairs of layers, using a result of a previous optimization to determine said prior first set of correction weights for each successive co-determination.
52. A method according to clause 48 or 49, wherein said prior first set of correction weights comprises the set of correction weights determined in a single layer optimization for said first layer.
53. A method according to any of clause 45 to 52, wherein said reference metrology data comprises overlay data and said parameter of interest is overlay between said second layer and said first layer.
54. A method according to any of clauses 45 to 53, wherein said first metrology corrections and second metrology corrections each comprise alignment corrections and first metrology data and second metrology data each comprise alignment data as referenced to a common reference layer.
55. A method according to clause 54, comprising applying said first set of correction weights to a first alignment measurement of a first layer on a substrate and said second set of correction weights to a second alignment measurement of a second layer on a substrate, each said first alignment measurement and second first alignment measurement being performed with a plurality of illumination settings such that each set of correction weights applies a weighting to measurements corresponding to the different illumination settings.
56. A method according to clause 55, comprising performing said first alignment measurement and said second alignment measurement.
57. A method according to clause 55 or 56, wherein the method is performed to determine said at least one set of correction weights in an initial training phase using training substrates, said determined at least one set of correction weights being for application to a plurality of subsequent substrates.
58. A method according to any of clauses 45 to 57, wherein said first metrology data and said second metrology data each relate to a common set of measurement locations.
59. A computer program comprising program instructions operable to perform the method of any of clauses 45 to 58, when run on a suitable apparatus.
60. A non-transient computer program carrier comprising the computer program of clause 59.
61. A processing system comprising a processor and a storage device comprising the computer program of clause 60.
62. An alignment sensor operable to perform the method of any of clauses 45 to 58.
63. A lithographic apparatus comprising: a patterning device support for supporting a patterning device; a substrate support for supporting a substrate; and the alignment sensor of clause 62.
64. A metrology device operable to perform the method of any of clauses 45 to 58.

The breadth and scope of the present invention should not be limited by any of the above-described exemplary embodiments, but should be defined only in accordance with the following claims and their equivalents.

1.-20. (canceled)

21. A method for determining at least one set of correction weights to correct metrology data, the method comprising:
obtaining first metrology data relating to a first set of illumination settings of measurement radiation used to perform a measurement of a first layer;
fitting the first metrology data to a model for representing the metrology data and determining a first set of fit residuals as the residuals of the first metrology data with respect to the model;
obtaining second metrology data relating to a second set of illumination settings of measurement radiation used to perform a measurement of a second layer, the second set of illumination settings comprising a plurality of illumination settings, where each illumination setting comprises a different wavelength, polarization or combination thereof;
fitting the second metrology data to a model for representing the metrology data and determining a second set of fit residuals as the residuals of the second metrology data with respect to the model; and
determining the at least one set of correction weights such that it minimizes a difference between the first set of fit residuals and the second set of fit residuals.

22. The method of claim 21, wherein the fitting step for the first metrology data comprises fitting the respective first metrology data and second metrology data per illumination setting with the model, and recording the fit residuals for each illumination setting.

23. The method of claim 21, wherein the determining the at least one set of correction weights comprises determining a single set of correction weights.

24. The method of claim 23, wherein the determining the single set of correction weights comprises determining second layer correction weights for correcting only the second set of metrology data, wherein the second layer comprises a top layer and the first layer comprises a layer below the second layer.

25. The method of claim 24, wherein the determining step comprises performing an optimization of the second layer correction weights such that they minimize a difference between the second set of fit residuals and a residual vector related to the first set of residual data.

26. The of claim 25, wherein the residual vector comprises a set of fit residuals per target or mark, determined from the first set of residual data and fixed first layer correction weights.

27. The method of claim 26, comprising performing an initial optimization on the first metrology data only to determine the first set of residual data and fixed first layer correction weights.

28. The method of claim 25, wherein the second set of fit residuals is comprised in a residual matrix comprising the metrology data arranged per target or mark in a first dimension and per illumination condition in a second dimension.

29. The method of claim 23, wherein the single set of correction weights comprises a common set of correction weights for correcting each of the first set of metrology data and the second set of metrology data.

30. The method of claim 29, wherein the determining step comprises performing an optimization of the common set of correction weights such that they minimize a difference between a first residual matrix comprising the first metrology data arranged per target or mark in a first dimension and per illumination condition in a second dimension and a second residual matrix comprising the second metrology data arranged per target or mark in the first dimension and per illumination condition in the second dimension.

31. The method of claim 21, wherein the determining the at least one set of correction weights comprises determining first layer correction weights for correcting the first metrology data and second layer correction weights for correcting the second metrology data.

32. The method of claim 31, wherein the determining step comprises performing a co-optimization of the first layer correction weights and the second layer correction weights such that they minimize a difference of the first set of fit residuals weighted by the first layer correction weights and the second set of fit residuals weighted by the second layer correction weights.

33. The method of claim 32, comprising imposing a prior weight receipt that minimizes a magnitude of the first set of fit residuals weighted by the first layer correction weights and a magnitude of the second set of fit residuals weighted by the second layer correction weights.

34. The method of claim 33, wherein the prior weight recipe is based on a first set of initial weights that optimize the first set of fit residuals towards zero and a second set of initial weights that optimize the second set of fit residuals toward zero.

35. The method of claim 34, comprising performing a first initial optimization on the first metrology data to obtain the first set of initial weights and a second initial optimization on the second metrology data to obtain the second set of initial weights.

36. The method of claim 21, wherein the first set of illumination settings and the second set of illumination settings comprise a common set of illumination settings.

37. The method of claim 21, wherein the first metrology data and the second metrology data each relate to a common set of measurement locations.

38. An alignment sensor operable to perform the method of claim 21.

39. A lithographic apparatus comprising:
a patterning device support for supporting a patterning device;
a substrate support for supporting a substrate; and
the alignment sensor of claim 38.

40. A metrology device operable to perform the method of claim 21.
